(19) United States
(12) Patent Application Publication
(10) Pub. No.: US 2024/0429884 A1
(43) Pub. Date: Dec. 26, 2024

(54) CIRCUIT TO CONTROL ACOUSTO-OPTIC MODULATORS FOR MEASURING ELECTROPHORETIC MOBILITY

(71) Applicant: Wyatt Technology, LLC, Goleta, CA (US)

(72) Inventors: David Rahmlow, Goleta, CA (US); Howard Friedenberg, Santa Barbara, CA (US)

(21) Appl. No.: 18/748,229

(22) Filed: Jun. 20, 2024

Related U.S. Application Data
(60) Provisional application No. 63/522,573, filed on Jun. 22, 2023.

(51) Int. Cl. H03F 3/24; G02F 1/11

(52) U.S. Cl. CPC H03F 3/245; G02F 1/113; H03F 2200/261; H03F 2200/451

(57) ABSTRACT

The present disclosure describes a circuit to control acousto-optic modulators for measuring electrophoretic mobility. In an embodiment, the circuit includes at least two channel amplifier circuits, a radio frequency generator logically coupled to the channel amplifier circuits, where the radio frequency generator is to output drive signals to the channel amplifier circuits, a synchronized data acquisition system logically coupled to the radio frequency generator, where the synchronized data acquisition system is to digitize an optical signal from a photo diode logically coupled to at least two acousto-optic modulators, and where one of the channel amplifier circuits is to drive one of acousto-optic modulators and the other of the channel amplifier circuits is to drive the other of the acousto-optic modulators, where the acousto-optic modulators and photo diode are to measure electrophoretic mobility of a sample.

### RELATED APPLICATION

This application claims the benefit of the earlier filing date of U.S. Provisional Patent Application Ser. No. 63/522,573, filed Jun. 22, 2023 and titled “Circuit to Control Acousto-Optic Modulators for Measuring Electrophoretic Mobility,” the entirety of which is incorporated herein by reference.

### BACKGROUND

The present disclosure relates to electrophoretic mobility, and more specifically, to a circuit to control acousto-optic modulators for measuring electrophoretic mobility.

### SUMMARY

The present disclosure describes a circuit to control acousto-optic modulators for measuring electrophoretic mobility. In an exemplary embodiment, the circuit includes (1) at least two channel amplifier circuits, (2) a radio frequency generator logically coupled to the at least two channel amplifier circuits, where the radio frequency generator is to output drive signals to the at least two channel amplifier circuits, (3) a synchronized data acquisition system logically coupled to the radio frequency generator, where the synchronized data acquisition system is to digitize an optical signal from a photo diode logically coupled to at least two acousto-optic modulators, and (4) where one of the at least two channel amplifier circuits is to drive one of the at least two acousto-optic modulators and the other of the at least two channel amplifier circuits is to drive the other of the at least two acousto-optic modulators, where the at least two acousto-optic modulators and the photo diode are to measure electrophoretic mobility of a sample.

In an exemplary embodiment, the circuit includes (1) at least two channel amplifier circuits logically coupled to a radio frequency generator, where the radio frequency generator is to output drive signals to the at least two channel amplifier circuits, (2) a synchronized data acquisition system logically coupled to the radio frequency generator, where the synchronized data acquisition system is to digitize an optical signal from a photo diode logically coupled to at least two acousto-optic modulators, and (3) where one of the at least two channel amplifier circuits is to drive one of at least two acousto-optic modulators and the other of the at least two channel amplifier circuits is to drive the other of the at least two acousto-optic modulators, where the at least two acousto-optic modulators and the photo diode are to measure electrophoretic mobility of a sample.

### BRIEF DESCRIPTION OF THE DRAWINGS

FIG. 1A depicts a circuit in accordance with an exemplary embodiment.

FIG. 1B depicts a circuit in accordance with an exemplary embodiment.

FIG. 1C depicts a circuit in accordance with an exemplary embodiment.

FIG. 2A depicts a circuit in accordance with an embodiment.

FIG. 2B depicts a circuit in accordance with an embodiment.

FIG. 2C depicts a circuit in accordance with an embodiment.

FIG. 3 depicts a graph in accordance with an embodiment.

### DETAILED DESCRIPTION

The present disclosure describes a circuit to control acousto-optic modulators for measuring electrophoretic mobility. In an exemplary embodiment, the circuit includes (1) at least two channel amplifier circuits, (2) a radio frequency generator logically coupled to the at least two channel amplifier circuits, where the radio frequency generator is to output drive signals to the at least two channel amplifier circuits, (3) a synchronized data acquisition system logically coupled to the radio frequency generator, where the synchronized data acquisition system is to digitize an optical signal from a photo diode logically coupled to at least two acousto-optic modulators, and (4) where one of the at least two channel amplifier circuits is to drive one of the at least two acousto-optic modulators and the other of the at least two channel amplifier circuits is to drive the other of the at least two acousto-optic modulators, where the at least two acousto-optic modulators and the photo diode are to measure electrophoretic mobility of a sample. In an embodiment, the radio frequency generator includes a direct digital synthesis circuit (DDS) (e.g., a computer chip). For example, the radio frequency generator is a direct digital synthesis circuit. In an embodiment, the synchronized data acquisition system includes (a) an analog to digital converter (ADC) logically coupled to the radio frequency generator (via e.g., FPGA, discrete logic), and (b) an electric field source logically coupled to the radio frequency generator. For example, the synchronized data acquisition system is to modulate the ADC and the electric field source.

In an exemplary embodiment, the circuit includes (1) at least two channel amplifier circuits logically coupled to a radio frequency generator, where the radio frequency generator is to output drive signals to the at least two channel amplifier circuits, (2) a synchronized data acquisition system logically coupled to the radio frequency generator, where the synchronized data acquisition system is to digitize an optical signal from a photo diode logically coupled to at least two acousto-optic modulators, and (3) where one of the at least two channel amplifier circuits is to drive one of at least two acousto-optic modulators and the other of the at least two channel amplifier circuits is to drive the other of the at least two acousto-optic modulators, where the at least two acousto-optic modulators and the photo diode are to measure electrophoretic mobility of a sample.

In an embodiment, the circuit could eliminate a significant zero-order peak caused by inter-channel drive coupling to the acousto-optic modulators. For example, the circuit could output drive signals to the acousto-optic modulators with a frequency in the range of 80 to 100 MHz with a radio frequency power of 2 W (33 dBm) for full efficiency of a reference intensity signal, I_{ref}, (e.g., −10 dB to −20 dB below full efficiency), a load of 50 ohms, 2:1 voltage standing wave ratio (VSWR), and a leakage of 0-order (e.g., <−40 dB).

### Definitions

### Particle

A particle may be a constituent of a liquid sample aliquot. Such particles may be molecules of varying types and sizes, nanoparticles, virus like particles, liposomes, emulsions, bacteria, and colloids. These particles may range in size on the order of nanometer to microns.

### Analysis of Macromolecular or Particle Species in Solution

The analysis of macromolecular or particle species in solution may be achieved by preparing a sample in an appropriate solvent and then injecting an aliquot thereof into a separation system such as a liquid chromatography (LC) column or field flow fractionation (FFF) channel where the different species of particles contained within the sample are separated into their various constituencies. Once separated generally based on size, mass, or column affinity, the samples may be subjected to analysis by means of light scattering, refractive index, ultraviolet absorption, electrophoretic mobility, and viscometric response.

### Light Scattering

Light scattering (LS) is a non-invasive technique for characterizing macromolecules and a wide range of particles in solution. The two types of light scattering detection frequently used for the characterization of macromolecules are static light scattering and dynamic light scattering.

### Dynamic Light Scattering

Dynamic light scattering is also known as quasi-elastic light scattering (QELS) and photon correlation spectroscopy (PCS). In a DLS experiment, time-dependent fluctuations in the scattered light signal are measured using a fast photodetector. DLS measurements determine the diffusion coefficient of the molecules or particles, which can in turn be used to calculate their hydrodynamic radius.

### Static Light Scattering

Static light scattering (SLS) includes a variety of techniques, such as single angle light scattering (SALS), dual angle light scattering (DALS), low angle light scattering (LALS), and multi-angle light scattering (MALS). SLS experiments generally involve the measurement of the absolute intensity of the light scattered from a sample in solution that is illuminated by a fine beam of light. Such measurement is often used, for appropriate classes of particles/molecules, to determine the size and structure of the sample molecules or particles, and, when combined with knowledge of the sample concentration, the determination of weight average molar mass. In addition, nonlinearity of the intensity of scattered light as a function of sample concentration may be used to measure interparticle interactions and associations.

### Multi-Angle Light Scattering

Multi-angle light scattering (MALS) is a SLS technique for measuring the light scattered by a sample into a plurality of angles. It is used for determining both the absolute molar mass and the average size of molecules in solution, by detecting how they scatter light. Collimated light from a laser source is most often used, in which case the technique can be referred to as multiangle laser light scattering (MALLS). The “multi-angle” term refers to the detection of scattered light at different discrete angles as measured, for example, by a single detector moved over a range that includes the particular angles selected or an array of detectors fixed at specific angular locations.

A MALS measurement requires a set of ancillary elements. Most important among them is a collimated or focused light beam (usually from a laser source producing a collimated beam of monochromatic light) that illuminates a region of the sample. The beam is generally plane-polarized perpendicular to the plane of measurement, though other polarizations may be used especially when studying anisotropic particles. Another required element is an optical cell to hold the sample being measured. Alternatively, cells incorporating means to permit measurement of flowing samples may be employed. If single-particles scattering properties are to be measured, a means to introduce such particles one-at-a-time through the light beam at a point generally equidistant from the surrounding detectors must be provided.

Although most MALS-based measurements are performed in a plane containing a set of detectors usually equidistantly placed from a centrally located sample through which the illuminating beam passes, three-dimensional versions also have been developed where the detectors lie on the surface of a sphere with the sample controlled to pass through its center where it intersects the path of the incident light beam passing along a diameter of the sphere. The MALS technique generally collects multiplexed data sequentially from the outputs of a set of discrete detectors. The MALS light scattering photometer generally has a plurality of detectors.

Normalizing the signals captured by the photodetectors of a MALS detector at each angle may be necessary because different detectors in the MALS detector (i) may have slightly different quantum efficiencies and different gains, and (ii) may look at different geometrical scattering volumes. Without normalizing for these differences, the MALS detector results could be nonsensical and improperly weighted toward different detector angles.

### Electrophoretic Light Scattering

Electrophoretic light scattering (ELS) is a technique used to measure the electrophoretic mobility of particles in dispersion, or molecules in solution. This mobility is often converted to Zeta potential to enable comparison of materials under different experimental conditions. The fundamental physical principle is that of electrophoresis. A dispersion is introduced into a cell containing two electrodes. An electrical field is applied to the electrodes, and particles or molecules that have a net charge, or more strictly a net zeta potential will migrate towards the oppositely charged electrode with a velocity, known as the mobility, that is related to their zeta potential.

When an electric field is applied to a sample, any charged objects in the sample will be influenced by that field. The extra movement that particles exhibit as a result of them experiencing the electric field is called the electrophoretic mobility. Its typical units are μm·cm/V·s (micrometer centimeter per Volt second) since it is a velocity [μm/s] per field strength [V/cm]. The electrophoretic mobility is the direct measurement from which the zeta potential can be derived (using either the Smoluchowski/Debye-Hückel approximations or the complete Henry function F(κa) to get from the mobility to a zeta potential).

### Acousto-Optic Modulator

An acousto-optic modulator (AOM) is a device which can be used for controlling the transmitted power of a laser beam with an electrical drive signal. It is based on the acousto-optic effect (i.e., the modification of the refractive index of some crystal or glass material by the oscillating mechanical strain of a sound wave (photoelastic effect)). Usually, an AOM is understood to be an intensity modulator; other acousto-optic devices are suitable for shifting the optical frequency (e.g., acousto-optic frequency shifter) or the spatial direction (e.g., acousto-optic deflectors).

The key element of an AOM is a transparent crystal (or a piece of glass) through which the light propagates. A piezoelectric transducer attached to the crystal obtains a strong oscillating electrical signal from an RF driver (often via an impedance matching device). The piezo transducer excites a sound wave with a frequency of the order of 100 MHz and with an acoustic wavelength which is typically between 10 m and 100 m and an acoustic power (e.g., of the order of 1 W to 10 W). The intense sound wave generates a traveling strain wave in the material. Through the photo-elastic effect, that leads to a traveling refractive index grating, at which light can experience Bragg diffraction; therefore, AOMs are sometimes called Bragg cells.

A transducer generates a sound wave, at which a light beam is partially diffracted. The diffraction angle is exaggerated; it is normally only of the order of 1°. For a very short interaction length in the modulator, one would operate in the Raman-Nath regime, where multiple diffraction orders are obtained. However, most AOMs operate in the Bragg regime, where there is a substantial diffraction efficiency for the first diffraction order and hardly any diffraction into other orders.

The optical frequency of the diffracted beam is increased or decreased by the frequency of the sound wave (depending on the propagation direction of the acoustic wave relative to the beam) and propagates in a slightly different direction. The frequency and direction of the diffracted beam depend on the frequency of the sound wave, whereas the acoustic power is the control for the diffracted optical power. For most applications, the slight change of optical frequency is irrelevant.

Typically, an AOM is placed in a small box, having two holes or optical windows on opposite sides for the laser beam going through, and a connector for the RF driver. Sometimes that box is placed on a rotating table for precise rotational adjustment.

### Current Technologies

An interferometer measures ELS by imparting a frequency shift to a reference light/signal (e.g., laser) such that when the reference signal is mixed with the measurement signal corresponding to the mobility of molecules in a sample, a small known shift in the signal (e.g., 10 kHz to 20 kHz) is obtained. If the molecules are moving in one-direction from an observer (e.g., a positive direction), the observed frequency could be 9.900 kHz, while if the molecules were moving in the other direction relative to the observer (e.g., negative direction), the observed frequency could be 10.100 kHz, indicating a positive and negative shift in the frequency. Current acousto-optic modulators shift the frequency of lasers by 50 MHz to 400 MHz.

There is a need to shift the frequency of the light/laser by 10 kHz, via an acousto-optic modulator (AOM). One AOM could be used to the frequency of the light/laser up by 80 MHz, while a second AOM could be used to shift the frequency of the light/laser down by 80.1 MHz, resulting in a 10 kHz net shift in the frequency of the light/laser. In order to achieve this, very good frequency stability needs to be imparted to each of the AOMS with very low cross-talk between the two channels associated with the two AOMS (i.e., isolating the two channels/two AOMS), such that the digitization of a signal measured by a photo diode coupled to the two AOMS is tied/related in stable way to the difference frequency/net shift in the frequency of the light/laser. Thus, there is a need for a circuit to control acousto-optic modulators for measuring electrophoretic mobility.

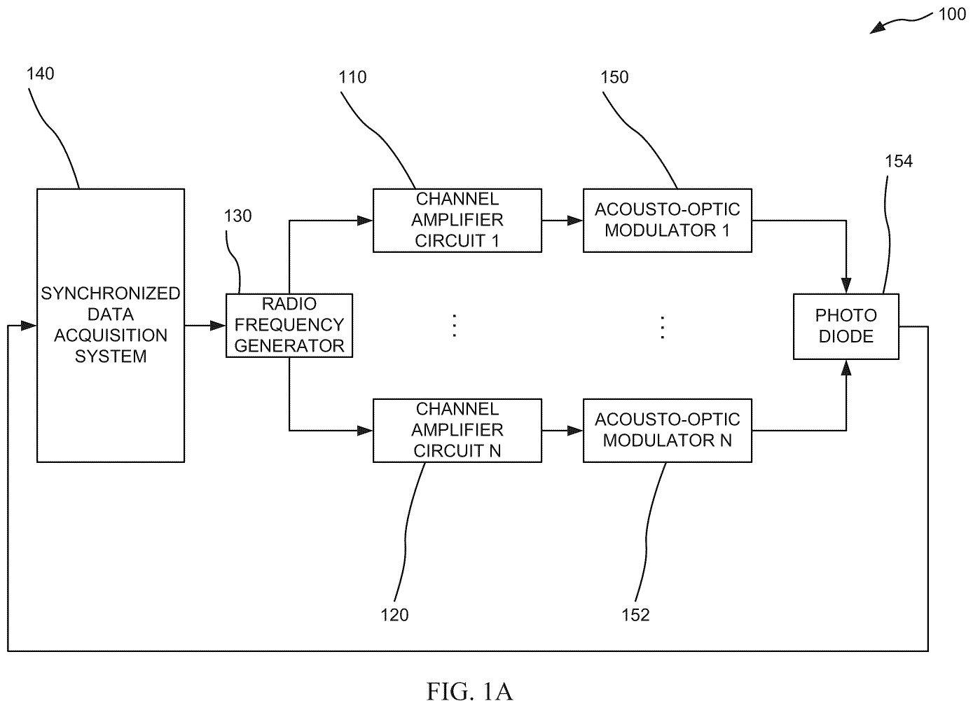

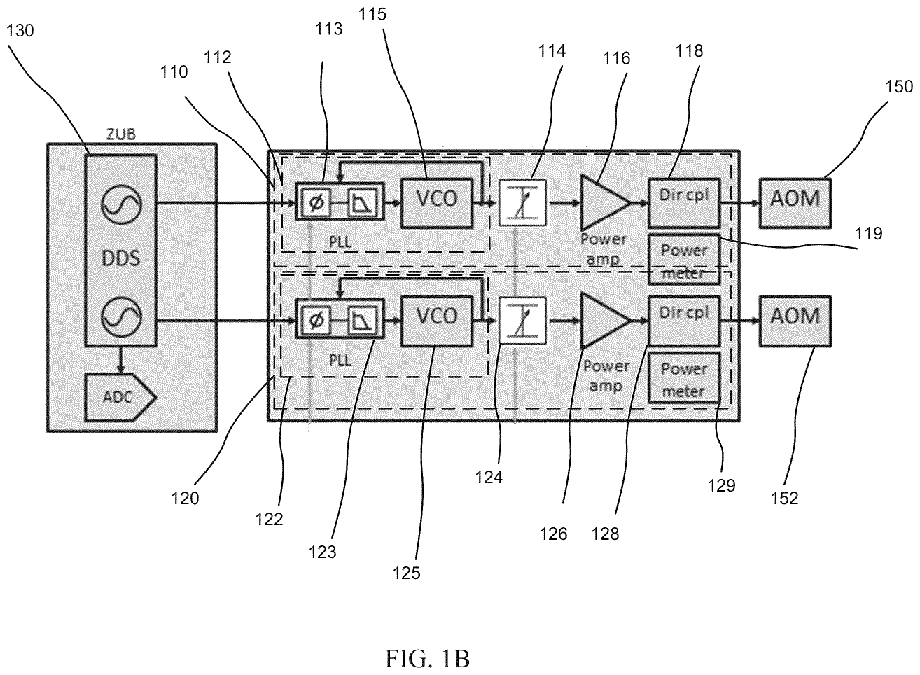

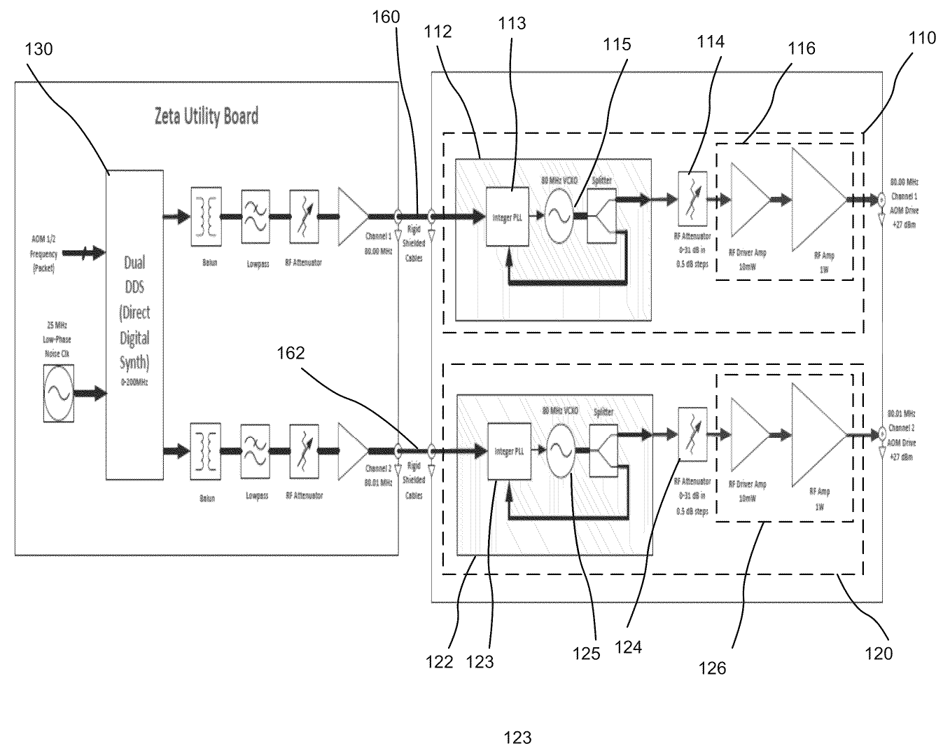

Referring to FIG. 1A, FIG. 1B, and FIG. 1C, in an exemplary embodiment, the circuit includes (1) at least two channel amplifier circuits 110, 120, (2) a radio frequency generator 130 logically coupled to at least two channel amplifier circuits 110, 120, where the radio frequency generator 130 is to output drive signals to at least two channel amplifier circuits 110, 120, (3) a synchronized data acquisition system 140 logically coupled to radio frequency generator 130, where synchronized data acquisition system 140 is to digitize an optical signal from a photo diode 154 logically coupled to at least two acousto-optic modulators 150, 152, and (4) where one of at least two channel amplifier circuits 110, 120 is to drive one of at least two acousto-optic modulators 150, 152 and the other of at least two channel amplifier circuits 110, 120 is to drive the other of at least two acousto-optic modulators 150, 152, where at least two acousto-optic modulators 150, 152 and photo diode 154 are to measure electrophoretic mobility of a sample. In an embodiment, radio frequency generator 130 and synchronized data acquisition system 140 are situated on a common circuit board, such that radio frequency generator 130 and synchronized data acquisition system 140 could be controlled by common control electronics, leading to synchronized frequency generation and data acquisition.

Referring to FIG. 1A, FIG. 1B, and FIG. 1C, in an exemplary embodiment, the circuit includes (1) at least two channel amplifier circuits 110, 120 logically coupled to a radio frequency generator 130, where the radio frequency generator 130 is to output drive signals to at least two channel amplifier circuits 110, 120, (2) a synchronized data acquisition system 140 logically coupled to radio frequency generator 130, where synchronized data acquisition system 140 is to digitize an optical signal from a photo diode 154 logically coupled to at least two acousto-optic modulators 150, 152, and (3) where one of at least two channel amplifier circuits 110, 120 is to drive one of at least two acousto-optic modulators 150, 152 and the other of at least two channel amplifier circuits 110, 120 is to drive the other of at least two acousto-optic modulators 150, 152, where at least two acousto-optic modulators 150, 152 and photo diode 154 are to measure electrophoretic mobility of a sample.

### Channel Amplifier Circuits

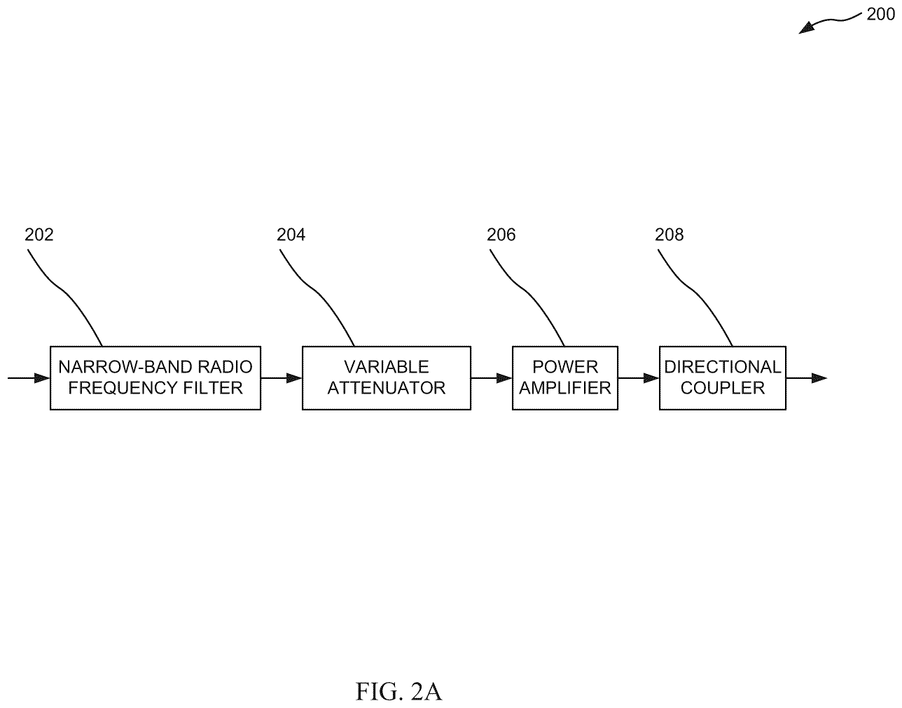

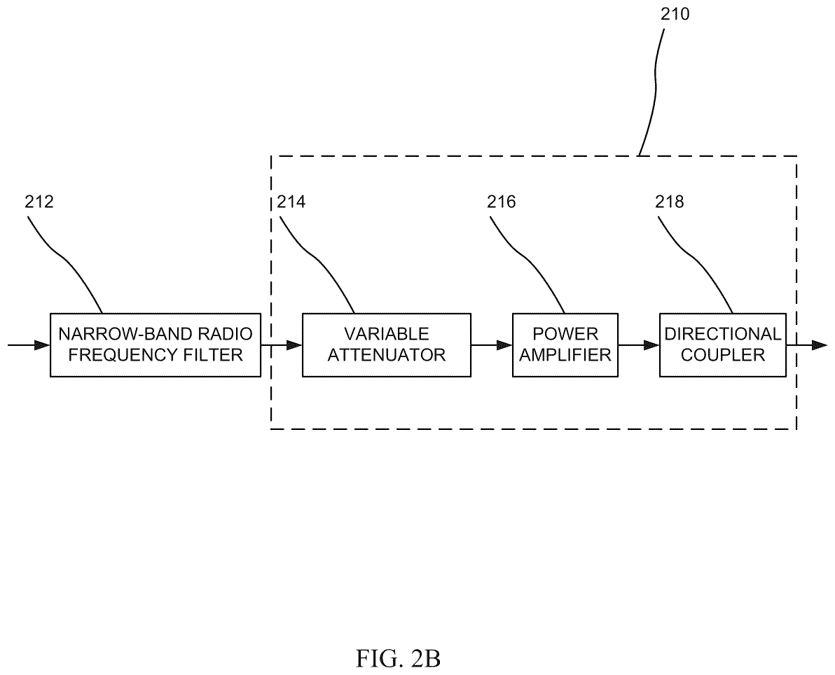

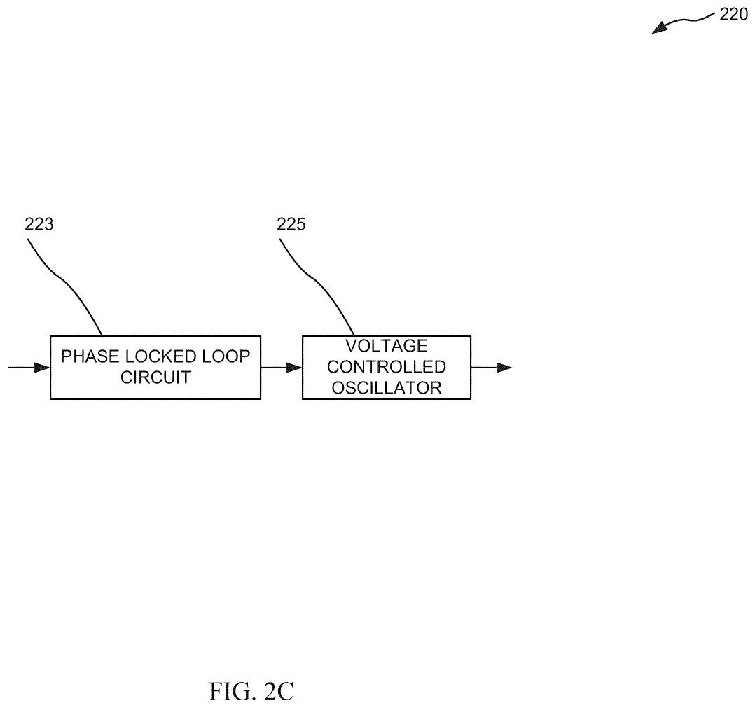

Referring to FIG. 1B and FIG. 2A, in an embodiment, each of at least two channel amplifier circuits 110, 120, 200 includes (a) a narrow-band radio frequency filter (NBRF) 112, 122, 202, (b) a variable attenuator 114, 124, 204 logically coupled to an output of narrow-band radio frequency filter 112, 122, 202, (c) a power amplifier 116, 126, 206 logically coupled to an output of variable attenuator 114, 124, 204, and (d) a directional coupler 118, 128, 208, logically coupled to an output of power amplifier 116, 126, 206. In an embodiment, narrow-band radio frequency filter 112, 122, 202 is a synchronous narrow-band radio frequency filter. Referring to FIG. 1B and FIG. 2B, in an embodiment, each of at least two channel amplifier circuits 110, 120, 210 includes (a) a variable attenuator 114, 124, 214 logically coupled to an output of a narrow-band radio frequency filter 112, 122, 212, (b) a power amplifier 116, 126, 216 logically coupled to an output of variable attenuator 114, 124, 214, and (c) a directional coupler 118, 128, 218, logically coupled to an output of power amplifier 116, 126, 216. In a further embodiment, each of at least two channel amplifier circuits 110, 120, 200, 210 further includes a power meter 119, 129, 209, 219.

Referring to FIG. 2C, in an embodiment, narrow-band radio frequency filter 112, 122, 202, 220 includes (i) a phase locked loop circuit 113, 123, 223 (PLL), and (ii) a voltage controlled oscillator 115, 125, 225 (VCO) logically coupled to an output of phase locked loop circuit 310. In an embodiment, narrow-band radio frequency filter 112, 122, 202, 300 minimizes crosstalk/cross coupling between channels associated with at least two acousto-optic modulators 150, 152, thereby leading to good isolation between the channels.

In an embodiment, narrow-band radio frequency filter 112, 122, 202, 220 is programmable. In an embodiment, narrow-band radio frequency filter 112, 122, 202, 220 is synchronous. In an embodiment, narrow-band radio frequency filter 112, 122, 202, 220 is selected from the group consisting of a crystal filter with a fixed band-notch at a chosen frequency, and a SAW filter with a fixed band notch filter at a chosen frequency.

### Radio Frequency Generator and Synchronized Data Acquisition System.

Referring to FIG. 1A, FIG. 1B, and FIG. 1C, radio frequency generator 130 and synchronized data acquisition system 140 are logically coupled to at least two channel amplifier circuits 110, 120 via cables 160, 162 that reduce crosstalk between channels associated with at least two channel amplifier circuits 110, 120. In an embodiment, cables 160, 162 are rigid shielded cables or double shielded cables. In an embodiment, cables 160, 162 are double shielded cables.

### Example

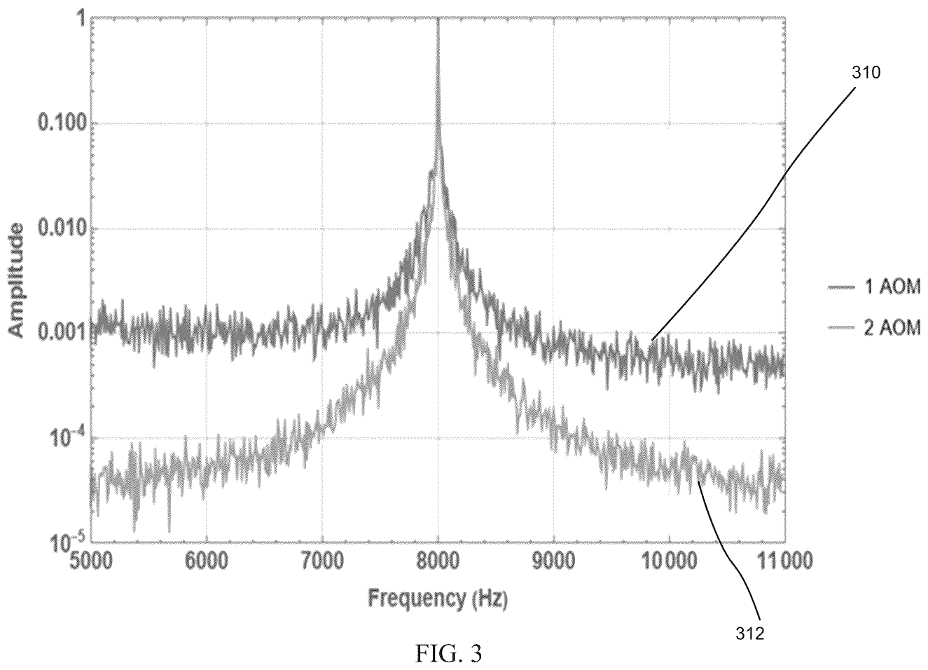

For example, FIG. 3 depicts the power spectrum output of a single AOM apparatus 310 versus the power spectrum output a dual AOM apparatus 312 controlled by the circuit described in the present disclosure. FIG. 3 shows that the dual AOM apparatus controlled by the circuit described in the present disclosure could achieve a lower and flatter noise floor (improved noise performance), through the use of audio-frequency electronics, and thus could achieve higher sensitivity in the intensity data.

What is claimed is:

1. A circuit comprising:
at least two channel amplifier circuits;
a radio frequency generator logically coupled to the at least two channel amplifier circuits,
wherein the radio frequency generator is to output drive signals to the at least two channel amplifier circuits;
a synchronized data acquisition system logically coupled to the radio frequency generator,
wherein the synchronized data acquisition system is to digitize an optical signal from a photo diode logically coupled to at least two acousto-optic modulators; and
wherein one of the at least two channel amplifier circuits is to drive one of the at least two acousto-optic modulators and the other of the at least two channel amplifier circuits is to drive the other of the at least two acousto-optic modulators,
wherein, the at least two acousto-optic modulators and the photo diode are to measure electrophoretic mobility of a sample.

2. The circuit of claim 1 wherein the radio frequency generator comprises a direct digital synthesis circuit.

3. The circuit of claim 1 wherein the synchronized data acquisition system comprises:
an analog to digital converter logically coupled to the radio frequency; and
an electric field source logically coupled to the radio frequency generator.

4. The circuit of claim 1 wherein the radio frequency generator and the synchronized data acquisition system are situated on a common circuit board.

5. The circuit of claim 1 wherein each of the at least two channel amplifier circuits comprises:
a narrow-band radio frequency filter;
a variable attenuator logically coupled to an output of the narrow-band radio frequency filter;
a power amplifier logically coupled to an output of the variable attenuator; and
a directional coupler logically coupled to an output of the power amplifier.

6. The circuit of claim 1 wherein each of the at least two channel amplifier circuits comprises:
a variable attenuator;
a power amplifier logically coupled to an output of the variable attenuator; and
a directional coupler logically coupled to an output of the power amplifier.

7. The circuit of claim 5 wherein the narrow-band radio frequency filter comprises:
a phase locked loop circuit; and
a voltage controlled oscillator logically coupled to an output of the phase locked loop.

8. The circuit of claim 5 wherein the narrow-band radio frequency filter is programmable.

9. The circuit of claim 5 wherein the narrow-band radio frequency filter is synchronous.

10. The circuit of claim 5 further comprising a power meter.

11. The circuit of claim 1 wherein the frequency generator and the synchronized data acquisition system are logically coupled to the at least two channel amplifier circuits via cables that reduce crosstalk between channels associated with the at least two channel amplifier circuits.

12. A circuit comprising:
at least two channel amplifier circuits logically coupled to a radio frequency generator,
wherein the radio frequency generator is to output drive signals to the at least two channel amplifier circuits;
a synchronized data acquisition system logically coupled to the radio frequency generator,
wherein the synchronized data acquisition system is to digitize an optical signal from a photo diode logically coupled to at least two acousto-optic modulators; and
wherein one of the at least two channel amplifier circuits is to drive one of the at least two acousto-optic modulators and the other of the at least two channel amplifier circuits is to drive the other of the at least two acousto-optic modulators,
wherein, the at least two acousto-optic modulators and the photo diode are to measure electrophoretic mobility of a sample.

13. The circuit of claim 12 wherein the radio frequency generator comprises a direct digital synthesis circuit.

14. The circuit of claim 12 wherein the synchronized data acquisition system comprises:
an analog to digital converter logically coupled to the radio frequency; and
an electric field source logically coupled to the radio frequency generator.

15. The circuit of claim 12 wherein the radio frequency generator and the synchronized data acquisition system are situated on a common circuit board.

16. The circuit of claim 12 wherein each of the at least two channel amplifier circuits comprises:
a narrow-band radio frequency filter;
a variable attenuator logically coupled to an output of the narrow-band radio frequency filter;
a power amplifier logically coupled to an output of the variable attenuator; and
a directional coupler logically coupled to an output of the power amplifier.

17. The circuit of claim 12 wherein each of the at least two channel amplifier circuits comprises:
a variable attenuator;
a power amplifier logically coupled to an output of the variable attenuator; and
a directional coupler logically coupled to an output of the power amplifier.

18. The circuit of claim 16 wherein the narrow-band radio frequency filter comprises:
a phase locked loop circuit; and
a voltage controlled oscillator logically coupled to an output of the phase locked loop.

19. The circuit of claim 16 further comprising a power meter.

20. The circuit of claim 12 wherein the frequency generator and the synchronized data acquisition system are logically coupled to the at least two channel amplifier circuits via cables that reduce crosstalk between channels associated with the at least two channel amplifier circuits.
